(19) United States
(12) Patent Application Publication
(10) Pub. No.: US 2024/0312878 A1
(43) Pub. Date: Sep. 19, 2024

(54) SEMICONDUCTOR DEVICE AND METHOD FOR PRODUCING SEMICONDUCTOR DEVICE

(71) Applicant: ROHM CO., LTD., Kyoto-shi (JP)

(72) Inventor: Hiroaki AOYAMA, Kyoto-shi (JP)

(21) Appl. No.: 18/677,332

(22) Filed: May 29, 2024

Related U.S. Application Data
(63) Continuation of application No. PCT/JP2022/044165, filed on Nov. 30, 2022.

(30) Foreign Application Priority Data
Dec. 13, 2021 (JP) 2021-201802

(51) Int. Cl. H01L 23/495; H01L 21/48; H01L 21/56; H01L 23/00; H01L 23/31

(52) U.S. Cl. CPC H01L 23/49531; H01L 21/4842; H01L 21/565; H01L 23/3107; H01L 24/16; H01L 2224/16245; H01L 2924/14252; H01L 2924/1426

(57) ABSTRACT

A semiconductor device includes: a lead including a main section that includes an obverse surface facing a first side in a thickness direction z; a semiconductor element supported by the obverse surface; and a sealing resin covering a portion of the lead and the semiconductor element. The lead includes a base member and a metal layer covering a portion of the base member. The lead includes a plurality of first terminal sections aligned in a first direction perpendicular to the thickness direction z. Each of the plurality of first terminal sections includes a first mounting surface facing a second side in the thickness direction, and a first side surface facing in a second direction perpendicular to the thickness direction z and the first direction. The first mounting surface and the first side surface are exposed from the sealing resin, and the first mounting surface and the first side surface are entirely formed of the metal layer.

### TECHNICAL FIELD

The present disclosure relates to a semiconductor device and a method for manufacturing the same.

### BACKGROUND ART

Various configurations have been proposed for a semiconductor device including a semiconductor element. JP-A-2018-190875 discloses an example of a conventional semiconductor device. The semiconductor device disclosed in this document includes a die pad, a plurality of terminals, a semiconductor element, and a sealing resin. The die pad and the terminals originate from a lead frame, and is made of a metal base material such as copper. The terminals are aligned in a direction perpendicular to a thickness direction. Each of the terminals has a terminal reverse surface and a terminal external surface that are exposed from the sealing resin. As a result, when the semiconductor device is mounted on a wiring board, a solder fillet is formed on the terminal external surface of each terminal. The solder fillets thus formed can improve the bonding strength of the semiconductor device to the wiring board.

The semiconductor device disclosed in JP-A-2018-190875 is provided in a QFN (Quad For Non-Lead) package. The QFN refers to a type in which a plurality of terminals do not protrude laterally from a sealing resin. In the conventional semiconductor device described above, each of the terminal external surfaces includes a surface portion of the metal base material which is exposed as a result of being cut together with the sealing resin by dicing. The surface portion of the metal base material at the terminal external surface has lower wettability to solder than, for example, a plated surface. This may lead to a decrease in the bonding strength of the solder fillet formed on the terminal external surface of each terminal.

### BRIEF DESCRIPTION OF THE DRAWINGS

FIG. 1 is a perspective view showing a semiconductor device according to a first embodiment of the present disclosure.

FIG. 2 is a plan view (seen through a sealing resin) showing the semiconductor device of FIG. 1.

FIG. 3 is a plan view (seen through a semiconductor element and the sealing resin) showing the semiconductor device of FIG. 1.

FIG. 4 is a bottom view showing the semiconductor device of FIG. 1.

FIG. 6 is a rear view showing the semiconductor device of FIG. 1.

FIG. 7 is a right-side view showing the semiconductor device of FIG. 1.

FIG. 8 is a left-side view showing the semiconductor device of FIG. 1.

FIG. 9 is a cross-sectional view along line IX-IX in FIG. 3.

FIG. 10 is a cross-sectional view along line X-X in FIG. 3.

FIG. 11 is a cross-sectional view along line XI-XI in FIG. 3.

FIG. 12 is a cross-sectional view along line XII-XII in FIG. 3.

FIG. 13 is a partially enlarged view of FIG. 12.

FIG. 14 is a partially enlarged view of FIG. 9.

FIG. 15 is a partially enlarged view of FIG. 4.

FIG. 16 is a cross-sectional view showing a step of an illustrative method for manufacturing the semiconductor device according to an embodiment of the present disclosure.

FIG. 17 is a cross-sectional view showing a step following the step of FIG. 16.

FIG. 18 is a cross-sectional view showing a step following the step of FIG. 17.

FIG. 19 is a schematic plan view showing the step of FIG. 18.

FIG. 20 is a cross-sectional view showing a step following the step of FIG. 18.

FIG. 21 is a plan view similar to FIG. 3, showing a semiconductor device according to a variation of the first embodiment.

FIG. 22 is a front view showing the semiconductor device of FIG. 21.

FIG. 23 is a rear view showing the semiconductor device of FIG. 21.

FIG. 24 is a right-side view showing the semiconductor device of FIG. 21.

FIG. 25 is a left-side view showing the semiconductor device of FIG. 21.

FIG. 26 is a cross-sectional view along line XXVI-XXVI in FIG. 21.

FIG. 27 is a cross-sectional view along line XXVII-XXVII in FIG. 21.

FIG. 28 is a partially enlarged view of FIG. 27.

FIG. 29 is a partially enlarged view of FIG. 26.

### DETAILED DESCRIPTION OF EMBODIMENTS

The following describes a preferred embodiment of the present disclosure in detail with reference to the drawings.

The terms such as “first”, “second” and “third” in the present disclosure are used merely as labels, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Furthermore, the phrase “an object A overlaps with an object B as viewed in a certain direction” includes, unless otherwise specified, “an object A overlaps with the entirety of an object B” and “an object A overlaps with a portion of an object B”.

### First Embodiment

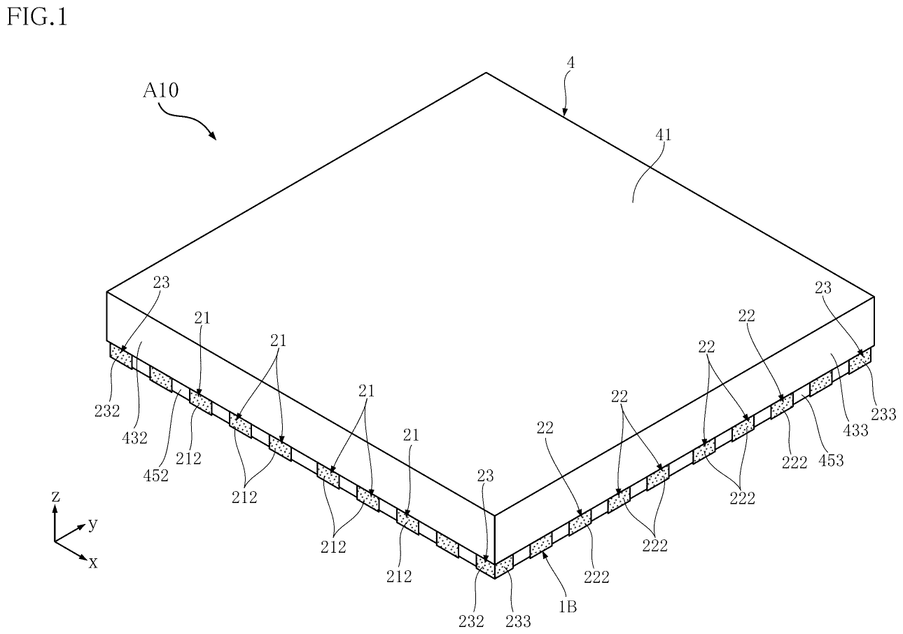

The following describes a semiconductor device according to a first embodiment of the present disclosure, with reference to FIGS. 1 to 15. A semiconductor device A10 of the present embodiment includes a lead 1, a semiconductor element 3, and a sealing resin 4. The lead 1 includes a main section 10, a plurality of first terminal sections 21, a plurality of second terminal sections 22, and a plurality of third terminal sections 23. The sealing resin 4 has a rectangular shape in plan view. As shown in FIG. 1, the package type of the semiconductor device A10 is a QFN (Quad For Non-Lead Package). The semiconductor element 3 is not limited to a specific configuration, and may be a flip-chip LSI (Large Scale Integration). In the present embodiment, the semiconductor element 3 is a flip-chip LSI having a switching circuit 321 and a control circuit 322 inside (details of these circuits are described below). In the semiconductor device A10, the switching circuit 321 converts DC power (voltage) into AC power (voltage). For example, the semiconductor device A10 is used for an element of a DC/DC converter circuit.

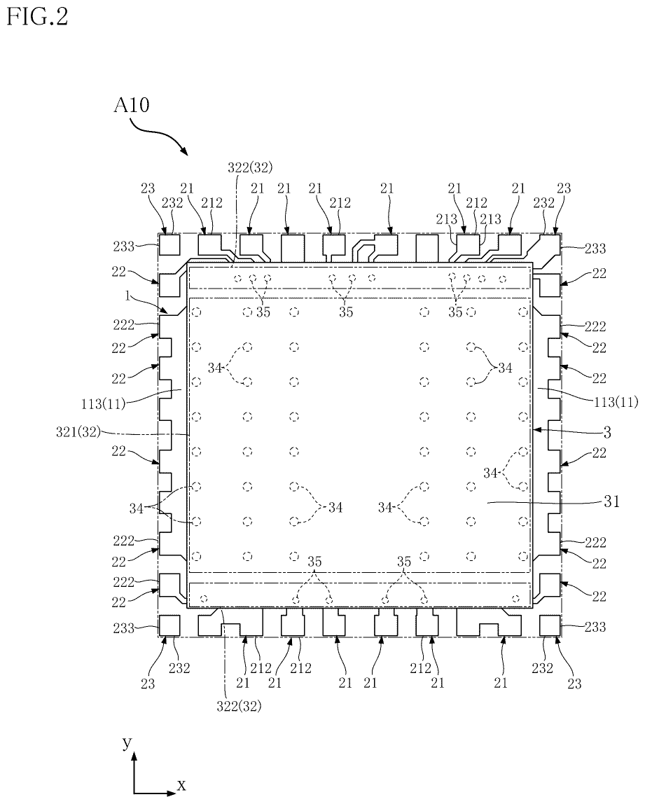

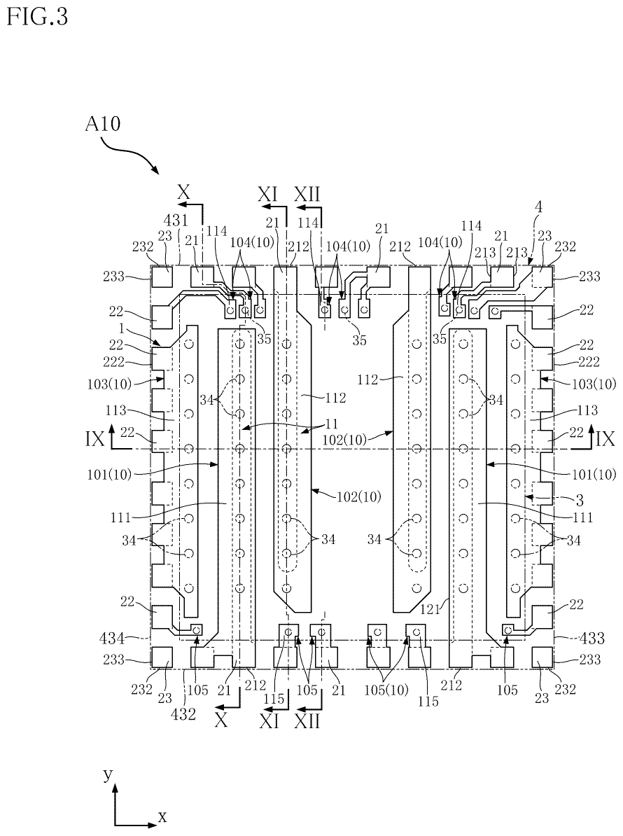

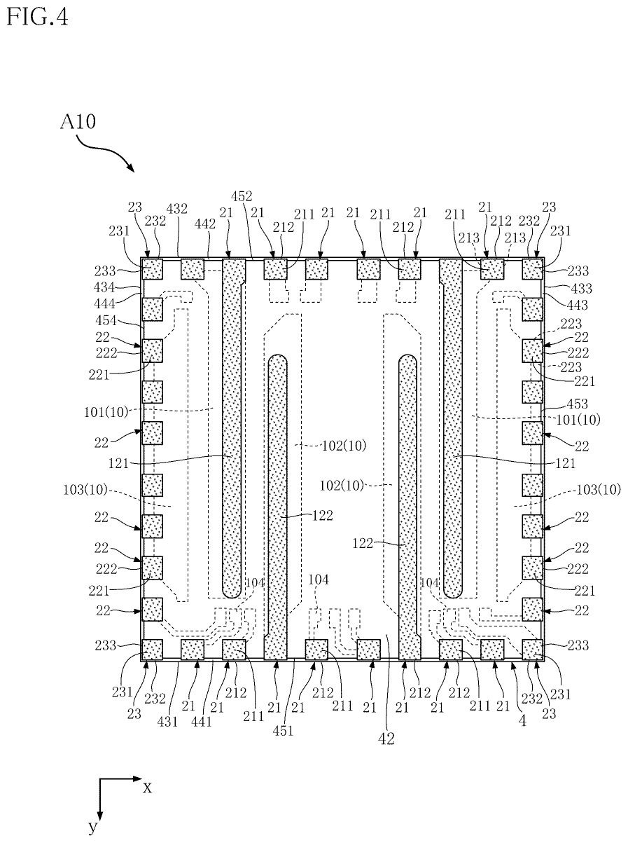

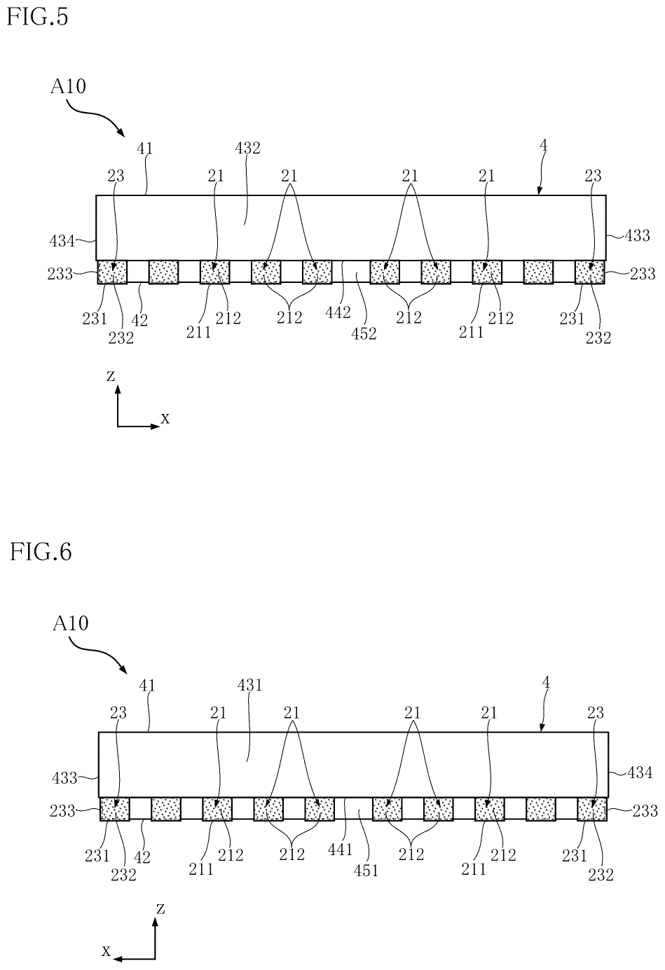

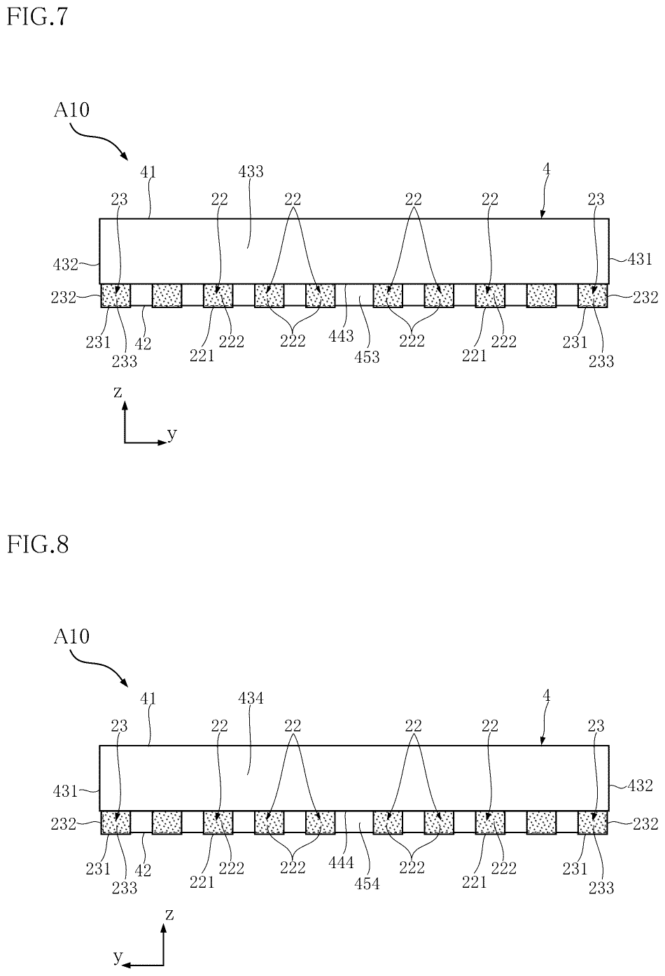

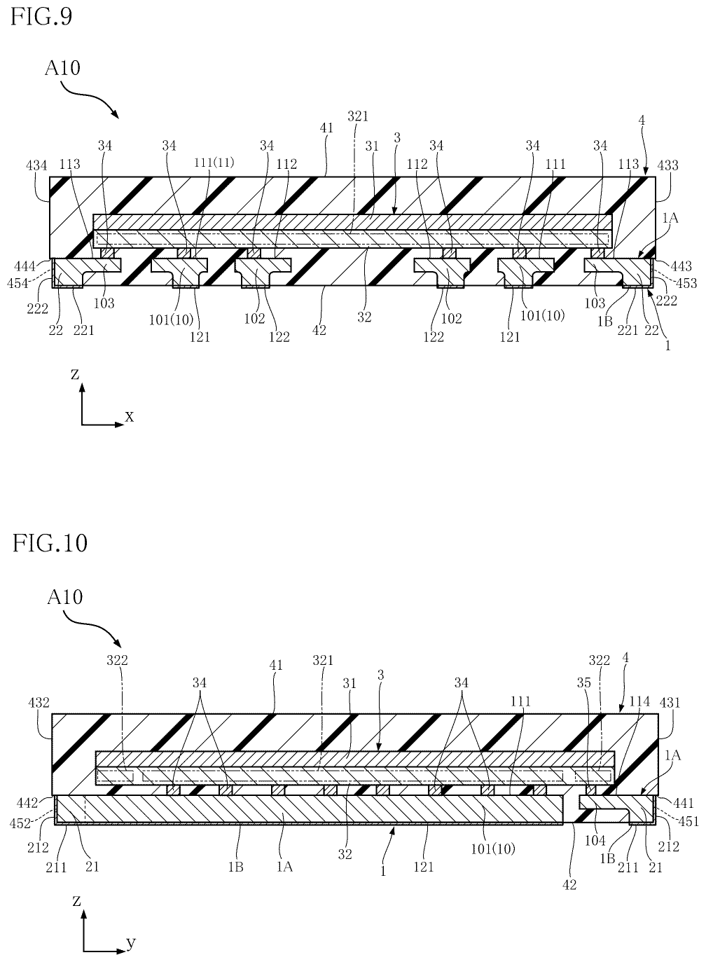

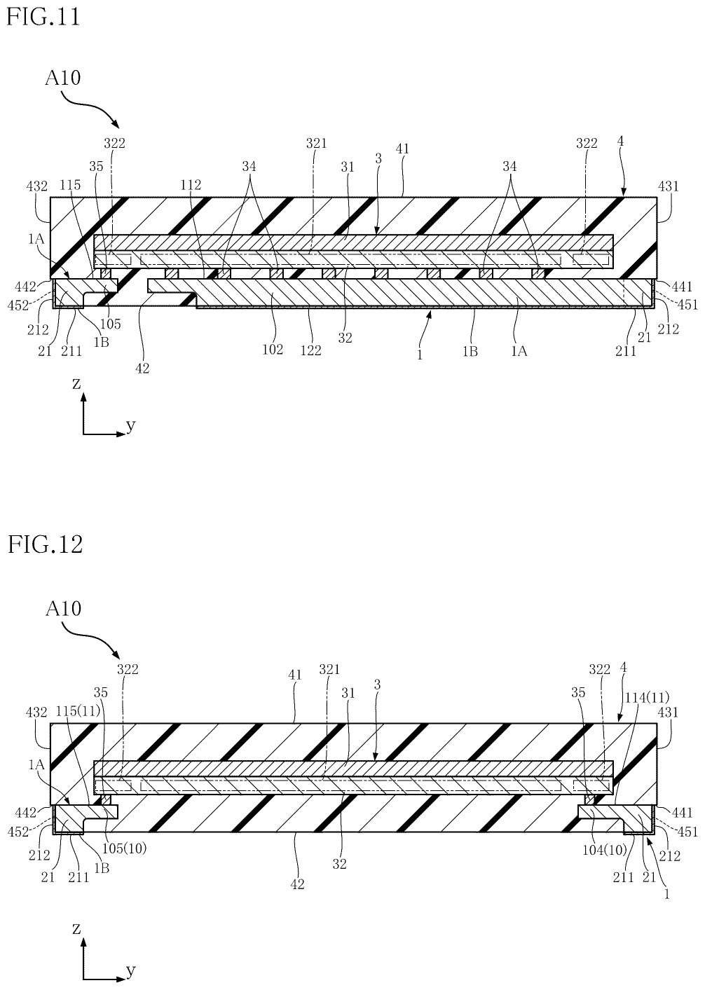

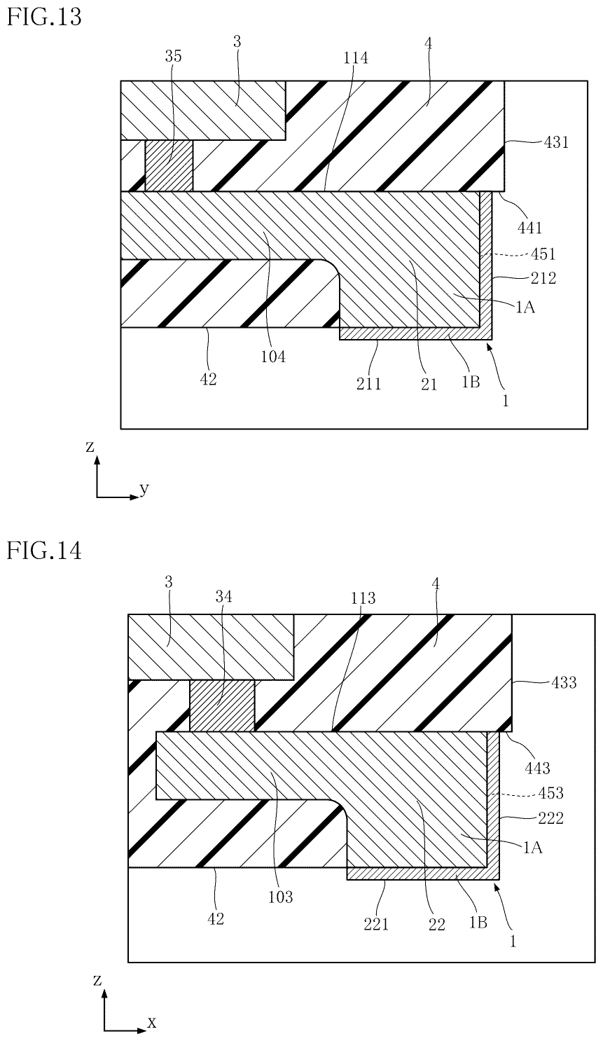

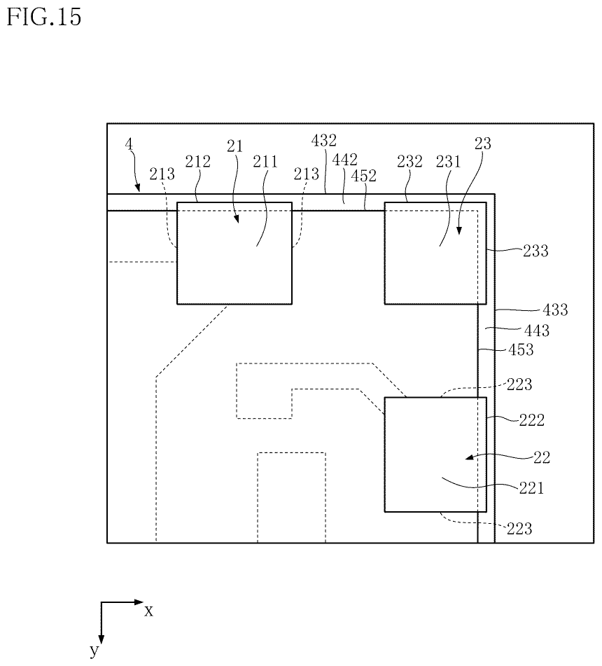

FIG. 1 is a perspective view showing the semiconductor device A10. FIG. 2 is a plan view showing the semiconductor device A10. FIG. 3 is a plan view showing the semiconductor device A10. FIG. 4 is a bottom view showing the semiconductor device A10. FIG. 5 is a front view showing the semiconductor device A10. FIG. 6 is a rear view showing the semiconductor device A10. FIG. 7 is a right-side view showing the semiconductor device A10. FIG. 8 is a left-side view showing the semiconductor device A10. FIG. 9 is a cross-sectional view along line IX-IX in FIG. 3. FIG. 10 is a cross-sectional view along line X-X in FIG. 3. FIG. 11 is a cross-sectional view along line XI-XI in FIG. 3. FIG. 12 is a cross-sectional view along line XII-XII in FIG. 3. FIG. 13 is a partially enlarged view of FIG. 12. FIG. 14 is a partially enlarged view of FIG. 9. FIG. 15 is a partially enlarged view of FIG. 4. For convenience of understanding, FIG. 2 shows the sealing resin 4 in phantom. For convenience of understanding, FIG. 3 shows the semiconductor element 3 and the sealing resin 4 in phantom. In these figures, the semiconductor element 3 and the sealing resin 4 are indicated by imaginary lines (two-dot chain lines).

In the description of the semiconductor device A10, the thickness direction of the main section 10 is referred to as a “thickness direction z”, for example. A direction (the horizontal direction in FIG. 2) perpendicular to the thickness direction z is referred to as a “first direction x”, for example. The direction (the vertical direction in FIG. 2) perpendicular to the thickness direction z and the first direction x is referred to as a “second direction y”, for example. As shown in FIGS. 1 and 2, the semiconductor device A10 has a rectangular shape as viewed in the thickness direction z. Furthermore, in the description of the semiconductor device A10, the right side in FIG. 2 is referred to as a “first side in the first direction x” and the left side in FIG. 2 is referred to as a “second side in the first direction x”, for convenience. The upper side in FIG. 2 is referred to as a “first side in the second direction y” and the lower side in FIG. 2 is referred to as a “second side in the second direction y”. The upper side in FIG. 5 is referred to as a “first side in the thickness direction z” and the lower side in FIG. 5 is referred to as a “second side in the thickness direction z”.

The lead 1 (the main section 10, the first terminal sections 21, the second terminal sections 22, and the third terminal sections 23) is, for example, constituted by a single lead frame. The lead 1 includes a base member 1A and a metal layer 1B (see FIGS. 9 to 14). The base member 1A is not limited to a particular material, and may be made of copper (Cu) or a copper alloy, for example. The metal layer 1B covers a portion of the base member 1A. The metal layer 1B is a plating layer formed on a surface of the base member 1A, for example. The plating layer is not limited to a particular material, and may be made of an alloy mainly containing tin (Sn), for example. In FIGS. 1 and 4 to 8, the metal layer 1B is indicated by a plurality of dotted areas.

As shown in FIGS. 3 and 9 to 12, the main section 10 supports the semiconductor element 3. At least a portion of the main section 10 is covered with the sealing resin 4. In the present embodiment, the main section 10 has an obverse surface 11 and a reverse surface 12. The obverse surface 11 faces a first side in the thickness direction z, and faces the semiconductor element 3. The reverse surface 12 faces the opposite side from the obverse surface 11 (a second side in the thickness direction z). The obverse surface 11 is covered with the sealing resin 4. The reverse surface 12 is exposed from the sealing resin 4.

In the present embodiment, the main section 10 includes a pair of first main sections 101, a pair of second main sections 102, a pair of third main sections 103, a plurality of fourth main sections 104, and a plurality of fifth main sections 105.

The obverse surface 11 has first obverse surfaces 111, second obverse surfaces 112, third obverse surfaces 113, fourth obverse surfaces 114, and fifth obverse surfaces 115. Each of the first obverse surfaces 111 to the fifth obverse surfaces 115 belongs to one of the first main sections 101 to the fifth main sections 105.

The reverse surface 12 has first reverse surfaces 121 and second reverse surfaces 122. Each of the first reverse surfaces 121 and the second reverse surfaces 122 belongs to one of the first main sections 101 and the second main sections 102.

As shown in FIG. 3, the pair of first main sections 101 are spaced apart from each other in the first direction x. One of the first main sections 101 is located on a first side in the first direction x (the right side in the figure) in the semiconductor device A10, and the other first main section 101 is located on a second side in the first direction x (the left side in the figure) in the semiconductor device A10. The pair of first main sections 101 extend in the second direction y. Each of the pair of first main sections 101 is an input terminal to which the DC power (voltage) to be converted in the semiconductor device A10 is inputted. The first main sections 101 are positive electrodes (P terminals).

As shown in FIGS. 3, 9, and 10, each of the first main sections 101 has a first obverse surface 111 and a first reverse surface 121. The semiconductor element 3 is supported by the first obverse surfaces 111. Each of the first main sections 101 has a portion exposed from the sealing resin 4 to the second side in the thickness direction z, and the exposed portion includes a first reverse surface 121. In the present embodiment, the first reverse surface 121 is formed of the metal layer 1B.

As shown in FIG. 3, the pair of second main sections 102 are spaced apart from each other in the first direction x. The pair of second main sections 102 are each arranged between the pair of first main sections 101 in the first direction x, and extend in the second direction y. One of the second main sections 102 is located on the first side in the first direction x (the right side in the figure) in the semiconductor device A10, is adjacent to one of the first main sections 101 (the one on the right side in the figure), and is arranged on the second side in the first direction x relative to the adjacent first main section 101. The other second main section 102 is located on the second side in the first direction x (the left side in the figure) in the semiconductor device A10, is adjacent to the other first main section 101 (the one on the left side in the figure), and is arranged on the first side in the first direction x relative to the adjacent first main section 101. Each of the pair of second main sections 102 outputs the AC power (voltage) resulting from the power conversion by the switching circuit 321 configured in the semiconductor element 3.

As shown in FIGS. 3, 9, and 11, each of the second main sections 102 has a second obverse surface 112 and a second reverse surface 122. The semiconductor element 3 is supported by the second obverse surfaces 112. Each of the second main sections 102 has a portion exposed from the sealing resin 4 to the second side in the thickness direction z, and the exposed portion includes a second reverse surface 122. In the present embodiment, the second reverse surface 122 is formed of the metal layer 1B.

As shown in FIG. 3, the pair of third main sections 103 are spaced apart from each other in the first direction x. The pair of third main sections 103 flank the first main sections 101 in the first direction x, and extend in the second direction y. One of the third main sections 103 is located on the first side in the first direction x (the right side in the figure) in the semiconductor device A10, is adjacent to one of the first main sections 101 (the one on the right side in the figure), and is arranged on the first side in the first direction x relative to the adjacent first main section 101. The other third main section 103 is located on the second side in the first direction x (the left side in the figure) in the semiconductor device A10, is adjacent to the other first main section 101 (the one on the left side in the figure), and is arranged on the second side in the first direction x relative to the adjacent first main section 101. Each of the pair of third main sections 103 is an input terminal to which the DC power (voltage) to be converted in the semiconductor device A10 is inputted. The third main sections 103 are negative electrodes (N terminals).

As shown in FIGS. 3 and 9, each of the third main sections 103 has a third obverse surface 113. The semiconductor element 3 is supported by the third obverse surfaces 113. Each of the third main sections 103 does not have a portion exposed from the sealing resin 4 to the second side in the thickness direction z.

As shown in FIG. 3, the fourth main sections 104 are located on a first side in the second direction y (the upper side in the figure) in the semiconductor device A10. Some of the fourth main sections 104 are located on the first side in the second direction y with respect to the first main sections 101. The rest of the fourth main sections 104 are located between the pair of second main sections 102 in the first direction X. Each of the fourth main sections 104 receives power (voltage) for driving the control circuit 322, or receives an electric signal to be transmitted to the control circuit 322, for example.

As shown in FIGS. 3, 10, and 12, each of the fourth main sections 104 has a fourth obverse surface 114. The semiconductor element 3 is supported by the fourth obverse surfaces 114. Each of the fourth main sections 104 does not have a portion exposed from the sealing resin 4 to the second side in the thickness direction z.

As shown in FIG. 3, the fifth main sections 105 are located on a second side in the second direction y (the lower side in the figure) in the semiconductor device A10. Some of the fifth main sections 105 are located on the second side in the second direction y with respect to the second main sections 102. The rest of the fifth main sections 105 are located on the second side in the second direction y with respect to the third main sections 103. Each of the fifth main sections 105 receives an electric signal to be transmitted to the control circuit 322, for example.

As shown in FIGS. 3, 11, and 12, each of the fifth main sections 105 has a fifth obverse surface 115. The semiconductor element 3 is supported by the fifth obverse surfaces 115. Each of the fifth main sections 105 does not have a portion exposed from the sealing resin 4 to the second side in the thickness direction z.

As shown in FIG. 3, the first terminal sections 21 are aligned in the first direction x. In the present embodiment, the first terminal sections 21 include those arranged at one end (the upper end in the figure) of the semiconductor device A10 (the sealing resin 4) in the second direction y, and those arranged at the other end (the lower end in the figure) of the semiconductor device A10 (the sealing resin 4) in the second direction y. In other words, each end of the semiconductor device A10 (the sealing resin 4) on the first side and the second side in the second direction y has a plurality of first terminal sections 21 aligned in the first direction x.

Each of the first terminal sections 21 arranged on the one end (the upper end in the figure) of the semiconductor device A10 in the second direction y is connected to one of the second main sections 102 and the fourth main sections 104. Each of the first terminal sections 21 arranged on the other end (the lower end in the figure) of the semiconductor device A10 in the second direction y is connected to one of the pair of first main sections 101 and the fifth main sections 105. The first terminal sections 21 each have the same configuration. Accordingly, the configuration of one of the first terminal sections 21 in the semiconductor device A10 will be described below as a representative.

As shown in FIGS. 3 to 6, 10 to 13, and 15, a first terminal section 21 has a first mounting surface 211, a first side surface 212, and two first inner surfaces 213. The first mounting surface 211 faces the second side in the thickness direction z. The first side surface 212 faces either the first side or the second side in the second direction y. In the present embodiment, a first side surface 212 is connected to a first mounting surface 211 and is flush with another one of first side surfaces 212. The first mounting surface 211 and the first side surface 212 are exposed from the sealing resin 4. The first mounting surface 211 and the first side surface 212 are entirely formed of the metal layer 1B. One of the two first inner surfaces 213 faces the first side in the first direction x and the other faces the second side in the first direction x. Each of the two first inner surfaces 213 is connected to the first mounting surface 211 and the first side surface 212. The two first inner surfaces 213 are covered with the sealing resin 4.

As shown in FIG. 3, the second terminal sections 22 are aligned in the second direction y. In the present embodiment, the second terminal sections 22 include those arranged at one end (the right end in the figure) of the semiconductor device A10 (the sealing resin 4) in the first direction x, and those arranged at the other end (the left end in the figure) of the semiconductor device A10 (the sealing resin 4) in the first direction x. In other words, each end of the semiconductor device A10 (the sealing resin 4) on the first side and the second side in the first direction x has a plurality of second terminal sections 22 aligned in the second direction y.

Each of the second terminal sections 22 arranged at one end (the right end in the figure) of the semiconductor device A10 in the first direction x is connected to one of the third main sections 103, the fourth main sections 104, and the fifth main sections 105. Each of the second terminal sections 22 arranged at the other end (the left end in the figure) of the semiconductor device A10 in the first direction x is connected to one of the third main sections 103, the fourth main sections 104, and the fifth main sections 105. The second terminal sections 22 each have the same configuration. Accordingly, the configuration of one of the second terminal sections 22 in the semiconductor device A10 will be described below as a representative.

As shown in FIGS. 3, 4, 7 to 9, 14, and 15, a second terminal section 22 has a second mounting surface 221, a second side surface 222, and two second inner surfaces 223. The second mounting surface 221 faces the second side in the thickness direction z. The second side surface 222 faces either the first side or the second side in the first direction x. In the present embodiment, a second side surface 222 is connected to a second mounting surface 221 and is flush with another one of second side surfaces 222. The second mounting surface 221 and the second side surface 222 are exposed from the sealing resin 4. The second mounting surface 221 and the second side surface 222 are entirely formed of the metal layer 1B. One of the two second inner surfaces 223 faces the first side in the second direction y and the other faces the second side in the second direction y. Each of the two second inner surfaces 223 is connected to the second mounting surface 221 and the second side surface 222. The two second inner surfaces 223 are covered with the sealing resin 4.

Each of the third terminal sections 23 is located closer to an end of the sealing resin 4 than the first terminal sections 21 in the first direction x and closer to an end of the sealing resin 4 than the second terminal sections 22 in the second direction y. In other words, each of the third terminal sections 23 is arranged at one of the four corners of the rectangular sealing resin 4 as viewed in the thickness direction z. In the semiconductor device A10, the plurality of (four) third terminal sections 23 are arranged at the four corners of the sealing resin 4, respectively.

The third terminal section 23 (the upper right corner in the figure) arranged on the first side in the first direction x and the first side in the second direction y in the semiconductor device A10 is connected to a fourth main section 104. The third terminal section 23 (the upper left corner in the figure) arranged on the second side in the first direction x and the first side in the second direction y in the semiconductor device A10 is connected to a fourth main section 104. The third terminal section 23 (the lower right corner in the figure) arranged on the first side in the first direction x and the second side in the second direction y in the semiconductor device A10 is not connected to the main section 10 (the first main sections 101 to the fifth main sections 105). The third terminal section 23 (the lower left corner in the figure) arranged on the second side in the first direction x and the second side in the second direction y in the semiconductor device A10 is not connected to the main section 10 (the first main sections 101 to the fifth main sections 105). The third terminal sections 23 each have the same configuration. Accordingly, the configuration of one of the third terminal sections 23 in the semiconductor device A10 will be described below as a representative.

As shown in FIGS. 3 to 8 and 15, a third terminal section 23 has a third mounting surface 231, a third side surface 232, and a fourth side surface 233. The third mounting surface 231 faces the second side in the thickness direction z. The third side surface 232 faces the same side as the first side surfaces 212 of some first terminal sections 21 and faces either the first side or the second side in the second direction y. The fourth side surface 233 faces the same side as the second side surfaces 222 of some second terminal sections 22 and faces either the first side or the second side in the first direction x. In the present embodiment, a third side surface 232 is connected to the third mounting surface 231 and flush with another one of third side surfaces 232. A fourth side surface 233 is connected to a third mounting surface 231 and a third side surface 232 and flush with another one of fourth side surfaces 233. The third mounting surface 231, the third side surface 232, and the fourth side surface 233 are exposed from the sealing resin 4. The third mounting surface 231, the third side surface 232, and the fourth side surface 233 are entirely formed of the metal layer 1B.

The semiconductor element 3 has a semiconductor substrate 31, a semiconductor layer 32, a plurality of electrodes 34, and a plurality of electrodes 35. As shown in FIGS. 9 to 12, the semiconductor substrate 31 supports the semiconductor layer 32, the electrodes 34, and the electrodes 35, which are located below the semiconductor substrate 31. The constituent material of the semiconductor substrate 31 is silicon (Si) or silicon carbide (SiC).

The semiconductor layer 32 is stacked on the semiconductor substrate 31 on the side opposite from the obverse surface 11 in the thickness direction z. The semiconductor layer 32 contains multiple types of p-type semiconductors and n-type semiconductors based on the difference in the amounts of elements to be doped. The semiconductor layer 32 includes the switching circuit 321 and the control circuit 322 electrically connected to the switching circuit 321. The switching circuit 321 may be a metal-oxide-semiconductor field-effect transistor (MOSFET) or an insulated gate bipolar transistor (IGBT). In the example of the semiconductor device A10, the switching circuit 321 is divided into two areas, i.e., a high-voltage area (upper arm circuit) and a low-voltage area (lower arm circuit). Each of the areas is formed with a single n-channel MOSFET. The control circuit 322 includes a gate driver for driving the switching circuit 321 and a bootstrap circuit corresponding to the high-voltage area of the switching circuit 321, and performs control for properly driving the switching circuit 321. Note that the semiconductor layer 32 further includes a wiring layer (not illustrated). The wiring layer electrically connects the switching circuit 321 and the control circuit 322 to each other.

As shown in FIGS. 9 to 12, the electrodes 34 and the electrodes 35 are arranged on the side opposite from the obverse surface 11 (the first obverse surfaces 111 to the fifth obverse surfaces 115) in the thickness direction z. The electrodes 34 and the electrodes 35 are in contact with the semiconductor layer 32.

The electrodes 34 are electrically connected to the switching circuit 321 of the semiconductor layer 32. Each of the electrodes 34 is connected to one of the first obverse surfaces 111 of the pair of first main sections 101, the second obverse surfaces 112 of the pair of second main sections 102, and the third obverse surfaces 113 of the pair of third main sections 103. As a result, the pair of first main sections 101, the pair of second main sections 102, and the pair of third main sections 103 are electrically connected to the switching circuit 321.

The electrodes 35 are electrically connected to the control circuit 322 of the semiconductor layer 32. Each of the electrodes 35 is connected to one of the fourth obverse surfaces 114 of the fourth main sections 104 and the fifth obverse surfaces 115 of the fifth main sections 105. As a result, the fourth main sections 104 and the fifth main sections 105 are electrically connected to the control circuit 322. The constituent material of the electrodes 34 and the electrodes 35 contains copper, for example.

As shown in FIGS. 5 to 8, the sealing resin 4 has a resin obverse surface 41, a resin reverse surface 42, two first resin side surfaces 431 and 432, two second resin side surfaces 433 and 434, two first resin intermediate surfaces 441 and 442, two second resin intermediate surfaces 443 and 444, two first resin inner side surfaces 451 and 452, and two second resin inner side surfaces 453 and 454. The constituent material of the sealing resin 4 is a black epoxy resin, for example.

As shown in FIGS. 9 to 12, the resin obverse surface 41 faces the same side as the obverse surface 11 (the first obverse surfaces 111 to the fifth obverse surfaces 115) in the thickness direction z. As shown in FIGS. 5 to 8, the resin reverse surface 42 faces the opposite side from the resin obverse surface 41. As shown in FIGS. 4 and 9 to 12, the first reverse surfaces 121 of the first main sections 101, the second reverse surfaces 122 of the second main sections 102, the first mounting surfaces 211 of the first terminal sections 21, the second mounting surfaces 221 of the second terminal sections 22, and the third mounting surfaces 231 of the third terminal sections 23 are exposed from the resin reverse surface 42 (the sealing resin 4).

As shown in FIGS. 7 and 8, the first resin side surface 431 is located at the end of the sealing resin 4 on the first side in the second direction y, and faces the first side in the second direction y. The first resin side surface 431 is connected to the resin obverse surface 41. As shown in FIGS. 4 and 10 to 13, the first side surfaces 212 of the first terminal sections 21 arranged at the end of the semiconductor device A10 on the first side in the second direction y are located inward of the sealing resin 4 from the first resin side surface 431 as viewed in the thickness direction z. As shown in FIGS. 4, 7, and 8, the third side surfaces 232 of the two third terminal sections 23 arranged at the respective ends of the semiconductor device A10 in the first direction x and at the end of the semiconductor device A10 on the first side in the second direction y are located inward of the sealing resin 4 from the first resin side surface 431 as viewed in the thickness direction z.

As shown in FIGS. 7 and 8, the first resin side surface 432 is located at the end of the sealing resin 4 on the second side in the second direction y, and faces the second side in the second direction y. The first resin side surface 432 is connected to the resin obverse surface 41. As shown in FIGS. 4 and 10 to 12, the first side surfaces 212 of the first terminal sections 21 arranged at the end of the semiconductor device A10 on the second side in the second direction y are located inward of the sealing resin 4 from the first resin side surface 432 as viewed in the thickness direction z. As shown in FIGS. 4, 7, and 8, the third side surfaces 232 of the two third terminal sections 23 arranged at the respective ends of the semiconductor device A10 in the first direction x and at the end of the semiconductor device A10 on the second side in the second direction y are located inward of the sealing resin 4 from the first resin side surface 432 as viewed in the thickness direction z.

As shown in FIGS. 5 and 6, the second resin side surface 433 is located at the end of the sealing resin 4 on the first side in the first direction x and faces the first side in the first direction x. The second resin side surface 433 is connected to the resin obverse surface 41. As shown in FIGS. 4, 9 and 14, the second side surfaces 222 of the second terminal sections 22 arranged at the end of the semiconductor device A10 on the first side in the first direction x are located inward of the sealing resin 4 from the second resin side surface 433 as viewed in the thickness direction z. As shown in FIGS. 4, 5, and 6, the fourth side surfaces 233 of the two third terminal sections 23 arranged at the end of the semiconductor device A10 on the first side in the first direction x and on the respective ends of the semiconductor device A10 in the second direction y are located inward of the sealing resin 4 from the second resin side surface 433 as viewed in the thickness direction z.

As shown in FIGS. 5 and 6, the second resin side surface 434 is located at the end of the sealing resin 4 on the second side in the first direction x and faces the second side in the first direction x. The second resin side surface 434 is connected to the resin obverse surface 41. As shown in FIGS. 4 and 9, the second side surfaces 222 of the second terminal sections 22 arranged at the end of the semiconductor device A10 on the second side in the first direction x are located inward of the sealing resin 4 from the second resin side surface 434 as viewed in the thickness direction z. As shown in FIGS. 4, 5, and 6, the fourth side surfaces 233 of the two third terminal sections 23 arranged at the end of the semiconductor device A10 on the second side in the first direction x and on the respective ends of the semiconductor device A10 in the second direction y are located inward of the sealing resin 4 from the second resin side surface 434 as viewed in the thickness direction z.

As shown in FIGS. 4 and 10 to 13, the first resin intermediate surface 441 is connected to the end of the first resin side surface 431 on the second side in the thickness direction z and faces the second side in the thickness direction z. The first resin intermediate surface 441 is located between some first side surfaces 212 (the first side surfaces 212 of the first terminal sections 21 arranged at the end of the semiconductor device A10 on the first side in the second direction y) and the first resin side surface 431 in the second direction y.

As shown in FIGS. 4 and 10 to 12, the first resin intermediate surface 442 is connected to the end of the first resin side surface 432 on the second side in the thickness direction z and faces the second side in the thickness direction z. The first resin intermediate surface 442 is located between some first side surfaces 212 (the first side surfaces 212 of the first terminal sections 21 arranged at the end of the semiconductor device A10 on the second side in the second direction y) and the first resin side surface 432 in the second direction y.

As shown in FIGS. 4, 9, and 14, the second resin intermediate surface 443 is connected to the end of the second resin side surface 433 on the second side in the thickness direction z and faces the second side in the thickness direction z. The second resin intermediate surface 443 is located between some second side surfaces 222 (the second side surfaces 222 of the second terminal sections 22 arranged at the end of the semiconductor device A10 on the first side in the first direction x) and the second resin side surface 433 in the first direction x.

As shown in FIGS. 4 and 9, the second resin intermediate surface 444 is connected to the end of the second resin side surface 434 on the second side in the thickness direction z, and faces the second side in the thickness direction z. The second resin intermediate surface 444 is located between some second side surfaces 222 (the second side surfaces 222 of the second terminal sections 22 arranged at the end of the semiconductor device A10 on the second side in the first direction x) and the second resin side surface 434 in the first direction x.

As shown in FIGS. 4, 6, and 10 to 12, the first resin inner side surface 451 is connected to the resin reverse surface 42 and faces the first side in the second direction y. As viewed in the thickness direction z, the first resin inner side surface 451 is located inward of the sealing resin 4 from the first resin side surface 431 and the first resin intermediate surface 441. The dimension of the first resin inner side surface 451 in the thickness direction z is the same or substantially the same as the dimension of the portion of each of the first terminal sections 21 that is constituted by the base member 1A in the thickness direction z.

As shown in FIGS. 4, 5, and 10 to 12, the first resin inner side surface 452 is connected to the resin reverse surface 42 and faces the second side in the second direction y. As viewed in the thickness direction z, the first resin inner side surface 452 is located inward of the sealing resin 4 from the first resin side surface 432 and the first resin intermediate surface 442. The dimension of the first resin inner side surface 452 in the thickness direction z is the same or substantially the same as the dimension of the portion of each of the first terminal sections 21 that is made of the base member 1A in the thickness direction z.

As shown in FIGS. 4, 7, and 9, the second resin inner side surface 453 is connected to the resin reverse surface 42 and faces the first side in the first direction x. As viewed in the thickness direction z, the second resin inner side surface 453 is located inward of the sealing resin 4 from the second resin side surface 433 and the second resin intermediate surface 443. The dimension of the second resin inner side surface 453 in the thickness direction z is the same or substantially the same as the portion of each second terminal section 22 that is made of the base member 1A in the thickness direction z.

As shown in FIGS. 4, 8, and 9, the second resin inner side surface 454 is connected to the resin reverse surface 42 and faces the second side in the first direction x. As viewed in the thickness direction z, the second resin inner side surface 454 is located inward of the sealing resin 4 from the second resin side surface 434 and the second resin intermediate surface 444. The dimension of the second resin inner side surface 454 in the thickness direction z is the same or substantially the same as the dimension of the portion of each second terminal section 22 that is made of the base member 1A in the thickness direction z.

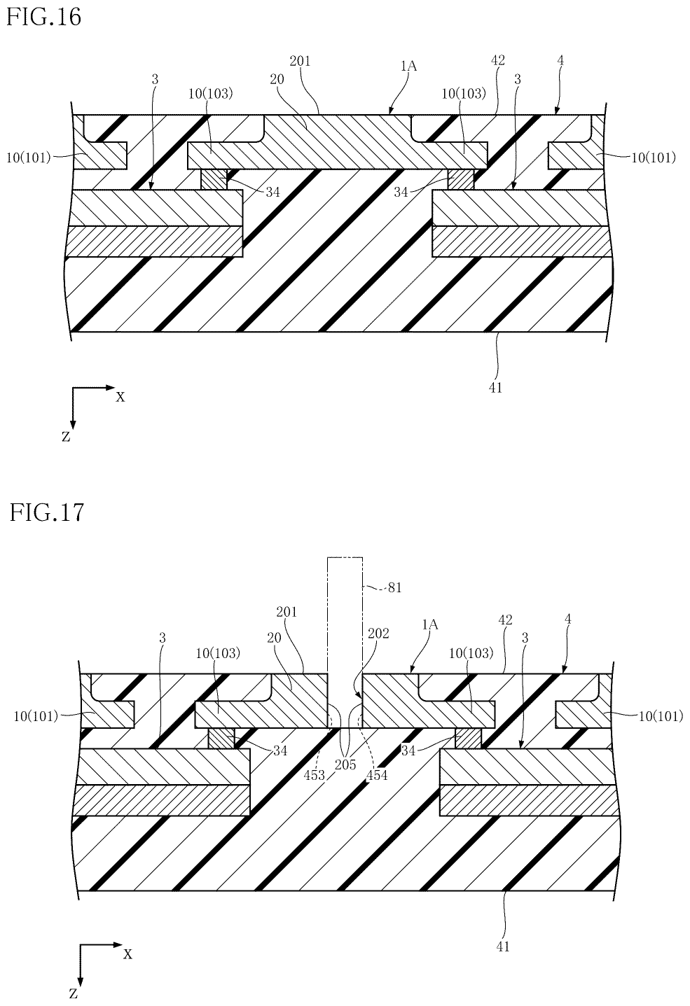

Next, an example of the method for manufacturing the semiconductor device A10 will be described with reference to FIGS. 16 to 20. FIGS. 16 to 18 and 20 are cross-sectional views each showing a step of the method for manufacturing the semiconductor device A10. Note that the cross sections shown in FIGS. 16 to 18 and 20 are taken along the same line as the cross section shown in FIG. 9.

First, as shown in FIG. 16, a sealing resin 4 is formed to cover portions of a plurality of terminal sections 20 and a semiconductor element 3. Each of the terminal sections 20 is made of a base member 1A. The sealing resin 4 is formed by compression molding. The surface (the upper surface in the figure) of a main section 10 (the portion made of the base member 1A) that faces the second side in the thickness direction z and mounting surfaces 201 of the terminal sections 20 are exposed from a resin reverse surface 42 of the sealing resin 4.

Next, as shown in FIG. 17, a groove 202 is formed in each of the terminal sections 20 such that the groove 202 is recessed from the mounting surface 201 in the thickness direction z. The groove 202 may be formed with use of a blade 81, for example. The formation of the groove 202 with the blade 81 is performed by cutting each of the terminal sections 20 through its entire thickness. In the illustrated example, the depth of the groove 202 (the dimension in the thickness direction z) coincides with or is slightly greater than the thickness of each terminal section 20 (the dimension in the thickness direction z). As a result of forming the groove 202 in each terminal section 20 with the blade 81, the terminal section 20 is divided into two portions with the blade 81 therebetween. The groove 202 has a pair of cut side surfaces 205 that face each other. The pair of cut side surfaces 205 are formed as a result of each terminal section 20 being cut.

In this step, the terminal sections 20 are cut off and the sealing resin 4 is dug along a plurality of lines extending in the first direction x and the second direction y, such that the depth of the groove 202 is constant. FIG. 17 shows the state where the terminal sections 20 and the sealing resin 4 are cut along a line extending in the second direction y. In the sealing resin 4, second resin inner side surfaces 453 and 454 (first resin inner side surfaces 451 and 452) are formed to be flush with the cut side surfaces 205.

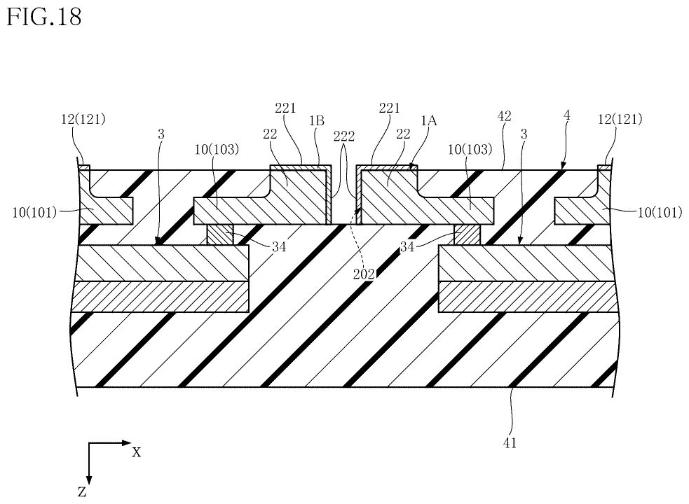

Next, as shown in FIG. 18, a metal layer 1B is formed to cover the mounting surface 201 and the cut side surfaces 205 (the surfaces of the groove 202) of each terminal section 20. The metal layer 1B is formed by electroless plating. With the metal layer 1B thus formed, the two separate portions of each terminal section 20 shown in FIG. 17 become two second terminal sections 22 each having a second mounting surface 221 and a second side surface 222. In the step of forming the metal layer 1B by electroless plating, the metal layer 1B is formed over the entire surface of the base member 1A exposed from the sealing resin 4. As a result, the second mounting surface 221 and the second side surface 222 of each second terminal section 22 are entirely formed of the metal layer 1B, as shown in FIG. 18. In this step, the metal layer 1B is also formed on the surface of the main section 10 (the portion made of the base member 1A) facing the second side in the thickness direction z, so that a reverse surface 12 made of the metal layer 1B is formed.

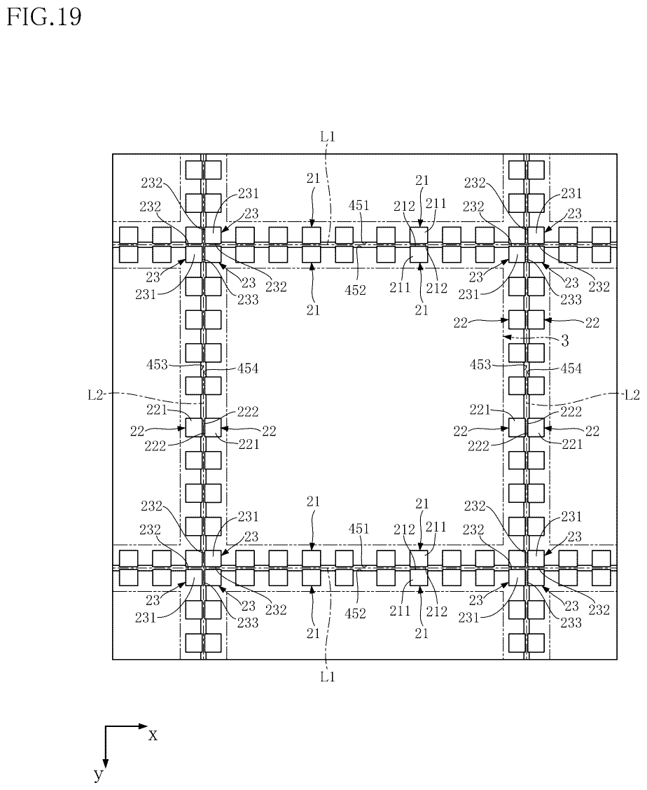

In the step shown in FIG. 17 described above, some terminal sections 20 are cut along the lines extending in the second direction y, and some terminal sections 20 are cut along the lines extending in the first direction x. The cutting of each terminal section 20 along the lines extending in the first direction x yields two separate portions for each terminal section 20. In the next step shown in FIG. 18, the two separate portions become two first terminal sections each having a first mounting surface 211 and a first side surface 212. The first mounting surface 211 and the first side surface 212 of each first terminal section 21 are entirely formed of the metal layer 1B. FIG. 19 is a schematic plan view of the step of FIG. 18 as viewed in the thickness direction z, and shows lines L1 extending in the first direction x, lines L2 extending in the second direction y, a plurality of first terminal sections 21, a plurality of second terminal sections 22, and a plurality of third terminal sections 23.

Furthermore, the area adjacent to an intersection between a line L1 extending in the first direction x and a line L2 extending in the second direction y is formed with four separate portions resulting from the cutting of a terminal section 20 in the step shown in FIG. 17. In the next step shown in FIG. 18, the four separate portions of the terminal section 20 become four third terminal sections 23 each having a third mounting surface 231, a third side surface 232, and a fourth side surface 233. The third mounting surface 231, the third side surface 232, and the fourth side surface 233 of each third terminal section 23 are entirely formed of the metal layer 1B.

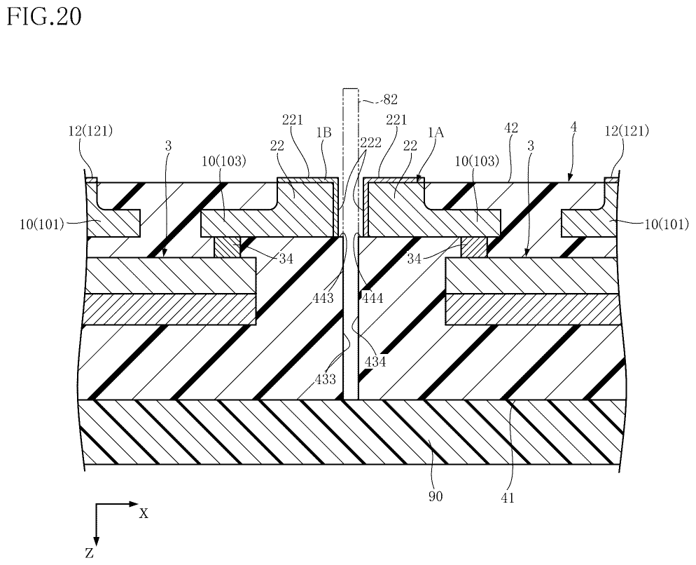

Next, as shown in FIG. 20, a tape 90 is attached to the resin obverse surface 41 of the sealing resin 4, and then the sealing resin 4 is cut with a blade 82 along the groove 202. At this point, the width of the blade 82 is set smaller than the distance between the pair of second side surfaces 222 of two second terminal sections 22 that face each other. With this step, the sealing resin 4 is diced into pieces each formed with first resin side surfaces 431 and 432, second resin side surfaces 433 and 434, first resin intermediate surfaces 441 and 442, and second resin intermediate surfaces 443 and 444. Through the above steps, a plurality of semiconductor devices A10 are obtained.

Next, advantages of the present embodiment will be described.

In the semiconductor device A10, a lead 1 includes a base member 1A and a metal layer 1B covering a portion of the base member 1A. The lead 1 includes a plurality of first terminal sections 21. The first terminal sections 21 are aligned in the first direction x. Each of the first terminal sections 21 has a first mounting surface 211 facing the second side in the thickness direction z, and a first side surface 212 facing in the second direction y. The first mounting surface 211 and the first side surface 212 are exposed from a sealing resin 4. Furthermore, the first mounting surface 211 and the first side surface 212 are entirely formed of the metal layer 1B. The metal layer 1B comprises a plating layer, and has higher wettability to solder than the base member 1A. Thus, when the semiconductor device A10 is bonded to a circuit board with solder, the first mounting surface 211 and the first side surface 212 are covered with solder appropriately. This makes it possible to increase the bonding strength of the solder fillet formed on the first side surface 212 of each first terminal section 21.

The sealing resin 4 has first resin side surfaces 431 and 432. Each of the first resin side surfaces 431 and 432 is located at an end of the sealing resin 4 in the second direction y and faces in the second direction y. As viewed in the thickness direction z, each of the first side surfaces 212 is located inward of the sealing resin 4 from the first resin side surfaces 431 and 432. With such a configuration, the metal layer 1B that forms the first side surfaces 212 is not cut with a blade or the like during the manufacture of the semiconductor device A10. This allows the entirety of each first side surface 212 to be more reliably formed of the metal layer 1B. This is more desirable for increasing the bonding strength of the solder fillets formed on the first side surfaces 212, and can improve mounting reliability when the semiconductor device A10 is mounted on a circuit board, for example.

The lead 1 includes a plurality of second terminal sections 22. The second terminal sections 22 are aligned in the second direction y. Each of the second terminal sections 22 has a second mounting surface 221 facing the second side in the thickness direction z, and a second side surface 222 facing in the first direction x. The second mounting surface 221 and the second side surface 222 are exposed from the sealing resin 4. Furthermore, the second mounting surface 221 and the second side surface 222 are entirely formed of the metal layer 1B. The metal layer 1B comprises a plating layer, and has higher wettability to solder than the base member 1A. Thus, when the semiconductor device A10 is bonded to a circuit board with solder, the second mounting surface 221 and the second side surface 222 are covered with solder appropriately. This makes it possible to increase the bonding strength of the solder fillet formed on the second side surface 222 of each second terminal section 22.

The sealing resin 4 has second resin side surfaces 433 and 434. Each of the second resin side surfaces 433 and 434 is located at an end of the sealing resin 4 in the first direction x and faces in the first direction x. As viewed in the thickness direction z, each of the second side surfaces 222 is located inward of the sealing resin 4 from the second resin side surfaces 433 and 434. With such a configuration, the metal layer 1B that forms the second side surfaces 222 is not cut with a blade or the like during the manufacture of the semiconductor device A10. This allows the entirety of each second side surface 222 to be more reliably formed of the metal layer 1B. This is more desirable for increasing the bonding strength of the solder fillets formed on the second side surfaces 222, and can improve mounting reliability when the semiconductor device A10 is mounted on a circuit board, for example.

The lead 1 includes a third terminal section 23. The third terminal section 23 is arranged at a position closer to an end of the sealing resin 4 than the first terminal sections 21 in the first direction x and closer to an end of the sealing resin 4 than the second terminal sections 22 in the second direction y. In other words, the third terminal section 23 is arranged at a corner of the sealing resin 4. The third terminal section 23 has a third mounting surface 231, a third side surface 232, and a fourth side surface 233. The third mounting surface 231 faces the second side in the thickness direction z. The third side surface 232 faces in the second direction y (the same side as the first side surfaces 212 of some first terminal sections 21). The fourth side surface 233 faces in the first direction x (the same side as the second side surfaces 222 of some second terminal sections 22). The third mounting surface 231, the third side surface 232, and the fourth side surface 233 are exposed from the sealing resin 4. Furthermore, the third mounting surface 231, the third side surface 232, and the fourth side surface 233 are entirely formed of the metal layer 1B. With such a configuration, when the semiconductor device A10 is bonded to a circuit board with solder, the third mounting surface 231 and two side surfaces (the third side surface 232 and the fourth side surface 233) are covered with solder appropriately. This makes it possible to increase the bonding strength of the solder fillets formed on the third side surface 232 and the fourth side surface 233 of the third terminal section 23. Furthermore, in the third terminal section 23 arranged at a corner of the sealing resin 4, a larger solder fillet is formed across the two side surfaces (the third side surface 232 and the fourth side surface 233). This is more desirable for increasing the bonding strength of the solder fillet, and can improve mounting reliability when the semiconductor device A10 is mounted on a circuit board, for example.

In the semiconductor device A10, a third terminal section 23 is arranged at each of the four corners of the sealing resin 4 having a rectangular shape as viewed in the thickness direction z. This makes it possible to increase the bonding strength of the solder fillets at the four corners of the sealing resin 4 (the semiconductor device A10) more efficiently. As a result, the mounting reliability of the semiconductor device A10 can be further improved.

### Variation of the First Embodiment

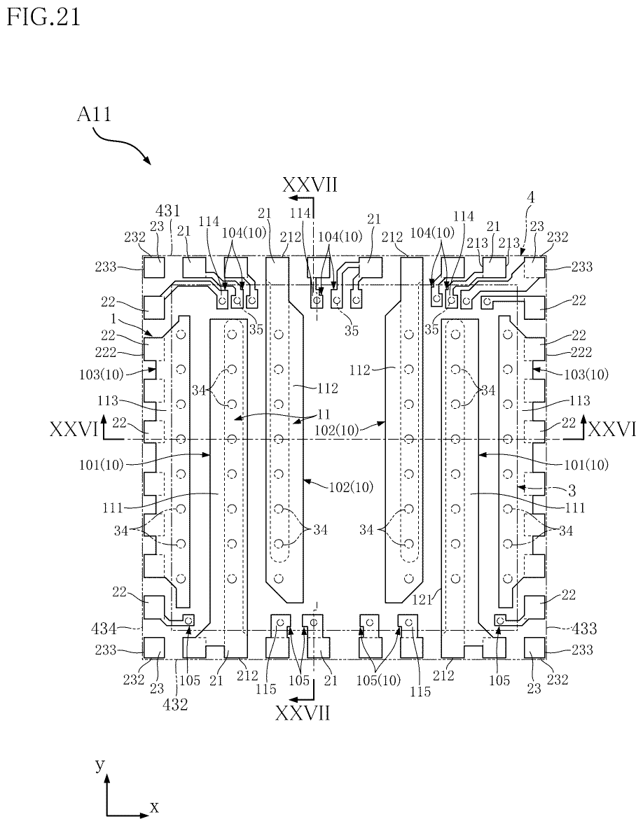

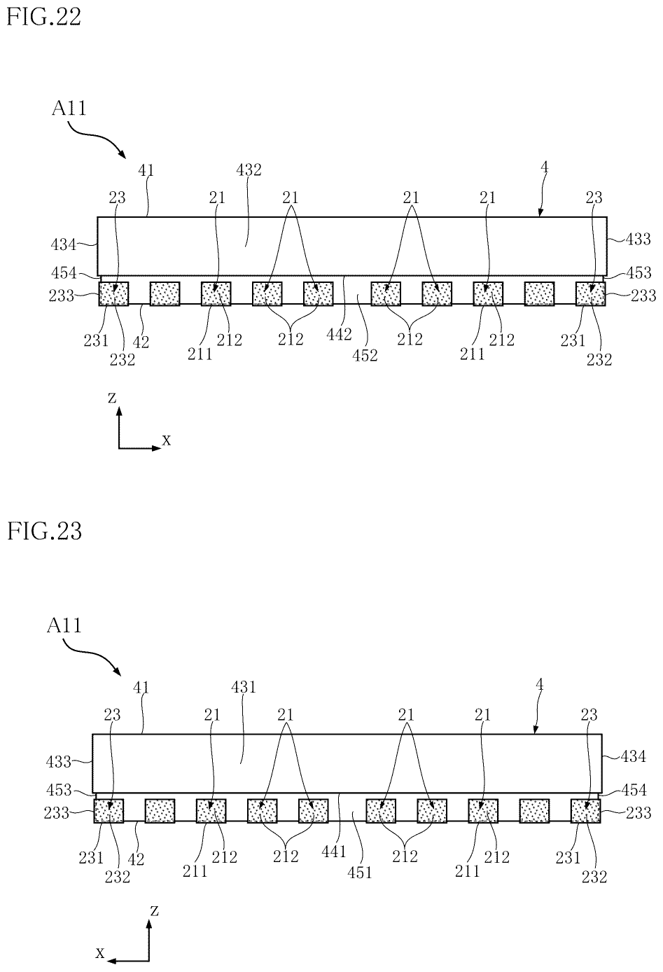

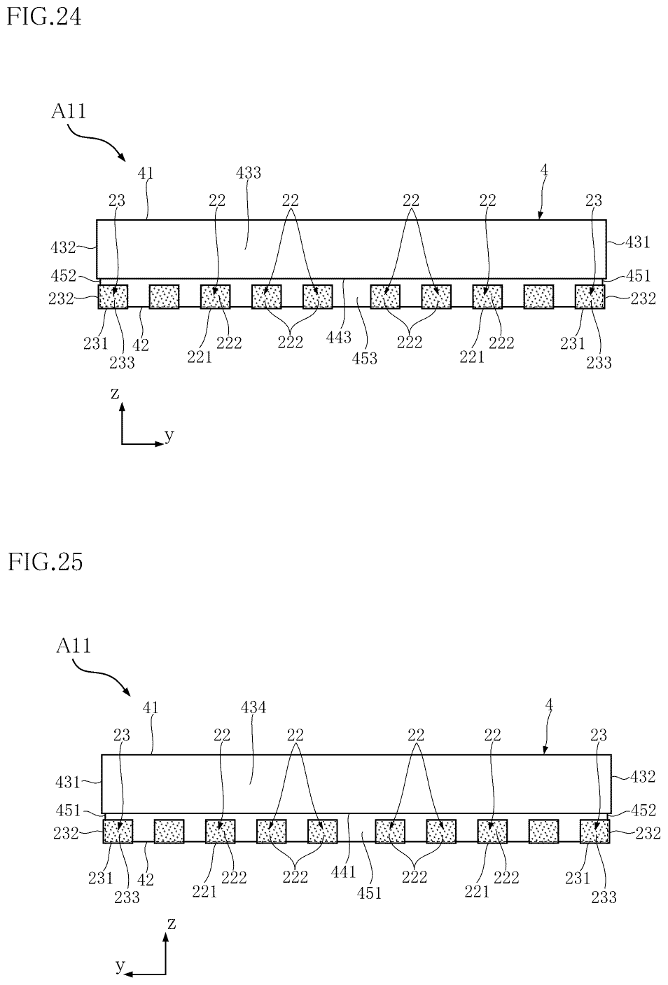

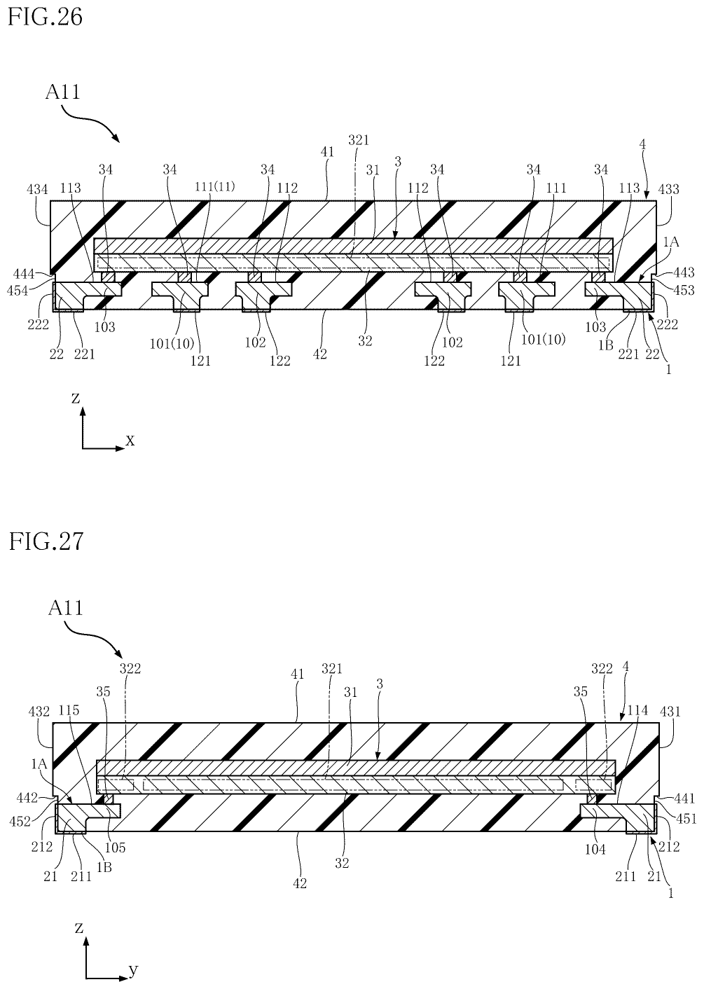

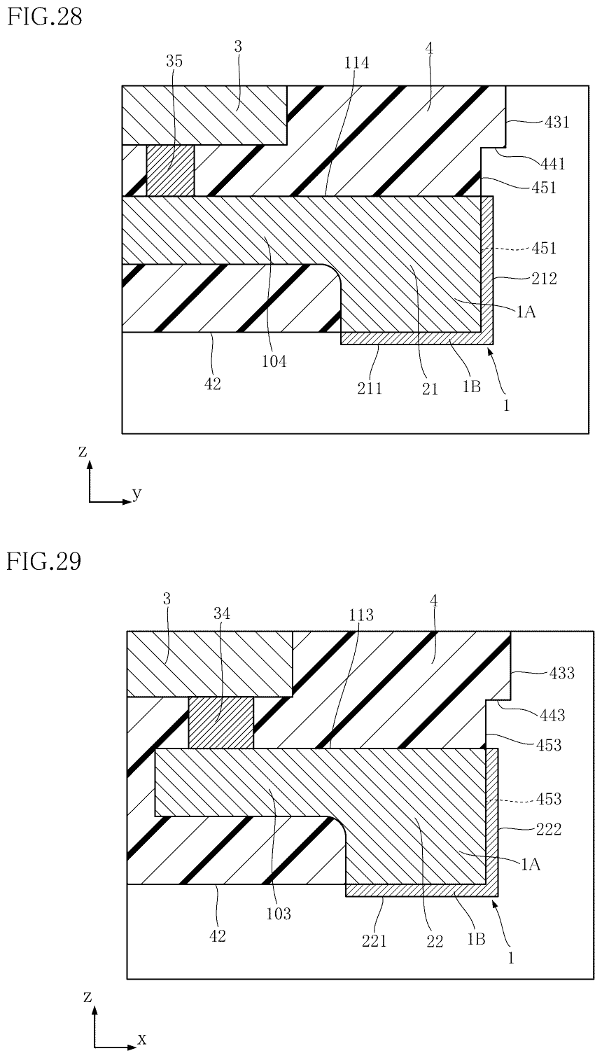

FIGS. 21 to 29 show a semiconductor device A11 according to a variation of the first embodiment. FIG. 21 is a plan view showing the semiconductor device A11. FIG. 22 is a front view showing the semiconductor device A11. FIG. 23 is a rear view showing the semiconductor device A11. FIG. 24 is a right-side view showing the semiconductor device A11. FIG. 25 is a left-side view showing the semiconductor device A11. FIG. 26 is a cross-sectional view along line XXVI-XXVI in FIG. 21. FIG. 27 is a cross-sectional view along line XXVII-XXVII in FIG. 21. FIG. 28 is a partially enlarged view of FIG. 27. FIG. 29 is a partially enlarged view of FIG. 26. In FIG. 21 and the subsequent drawings, the elements that are identical with or similar to those of the semiconductor device A10 in the above embodiment are designated by the same reference numerals as in the above embodiment, and the descriptions thereof are omitted as appropriate. For convenience of understanding, FIG. 21 shows the semiconductor element 3 and the sealing resin 4 in phantom. In FIG. 21, the semiconductor element 3 and the sealing resin 4 are indicated by imaginary lines (two-dot chain lines).

The semiconductor device A11 of the present variation is different from the semiconductor device in the above embodiment mainly in the configurations of the two first resin inner side surfaces 451 and 452 and the two second resin inner side surfaces 453 and 454 of the sealing resin 4. In the present variation, the dimension of each of the first resin inner side surfaces 451 and 452 in the thickness direction z is clearly larger than the dimension of the portion of each of the first terminal sections 21 that is made of the base member 1A in the thickness direction z. The dimension of each of the second resin inner side surfaces 453 and 454 in the thickness direction z is clearly larger than the dimension of the portion of each of the second terminal sections 22 that is made of the base member 1A in the thickness direction z. The first resin inner side surfaces 451 and 452 and the second resin inner side surfaces 453 and 454 that have the configurations as described above can be formed through the following procedure in a step of the method for manufacturing of the semiconductor device A10 which is described with reference to FIG. 17. The first resin inner side surfaces 451 and 452 and the second resin inner side surfaces 453 and 454 of the present variation can be formed by cutting each of the terminal sections 20 through its entire thickness with the blade 81 and cutting deeper to a portion of the sealing resin 4 located on the first side in the thickness direction z relative to the terminal sections 20.

According to the semiconductor device A11 of the present variation, the first mounting surface 211 and the first side surface 212 of each first terminal section 21 are entirely formed of the metal layer 1B. The metal layer 1B comprises a plating layer, and has higher wettability to solder than the base member 1A. Thus, when the semiconductor device A11 is bonded to a circuit board with solder, the first mounting surface 211 and the first side surface 212 are covered with solder appropriately. This makes it possible to increase the bonding strength of the solder fillet formed on the first side surface 212 of each first terminal section 21. The semiconductor device A11 also has advantages similar to those of the semiconductor device A10 in the above embodiment.

The semiconductor device according to the present disclosure is not limited to the above embodiment. Various design changes can be made to the specific configurations of the elements of the semiconductor device according to the present disclosure.

The present disclosure includes the embodiments described in the following clauses.

### Clause 1

A semiconductor device comprising:
a lead including a main section that includes an obverse surface facing a first side in a thickness direction;
a semiconductor element supported by the obverse surface; and
a sealing resin covering a portion of the lead and the semiconductor element,
wherein the lead includes a base member and a metal layer covering a portion of the base member,
the lead includes a plurality of first terminal sections aligned in a first direction perpendicular to the thickness direction,
each of the plurality of first terminal sections includes a first mounting surface facing a second side in the thickness direction, and a first side surface facing in a second direction perpendicular to the thickness direction and the first direction,
the first mounting surface and the first side surface are exposed from the sealing resin, and
the first mounting surface and the first side surface are entirely formed of the metal layer.

### Clause 2

The semiconductor device according to clause 1, wherein the sealing resin includes a first resin side surface located at an end in the second direction and facing in the second direction, and
the first side surface is located inward of the sealing resin from the first resin side surface as viewed in the thickness direction.

### Clause 3

The semiconductor device according to clause 2, wherein the sealing resin includes a first resin intermediate surface connected to an end of the first resin side surface on the second side in the thickness direction, and
the first resin intermediate surface faces the second side in the thickness direction and is located between the first side surface and the first resin side surface in the second direction.

### Clause 4

The semiconductor device according to any of clauses 1 to 3, wherein the first side surface is connected to the first mounting surface and flush with another one of the first side surfaces.

### Clause 5

The semiconductor device according to any of clauses 1 to 4, wherein the lead includes a plurality of second terminal sections aligned in the second direction,
each of the plurality of second terminal sections includes a second mounting surface facing the second side in the thickness direction, and a second side surface facing in the first direction,
the second mounting surface and the second side surface are exposed from the sealing resin, and
the second mounting surface and the second side surface are entirely formed of the metal layer.

### Clause 6

The semiconductor device according to clause 5, wherein the sealing resin includes a second resin side surface located at an end in the first direction and facing in the first direction, and
the second side surface is located inward of the sealing resin from the second resin side surface as viewed in the thickness direction.

### Clause 7

The semiconductor device according to clause 6, wherein the sealing resin includes a second resin intermediate surface connected to an end of the second resin side surface on the second side in the thickness direction, and
the second resin intermediate surface faces the second side in the thickness direction and is located between the second side surface and the second resin side surface in the first direction.

### Clause 8

The semiconductor device according to any of clauses 5 to 7, wherein the second side surface is connected to the second mounting surface and flush with another one of the second side surfaces.

### Clause 9

The semiconductor device according to any of clauses 5 to 8, wherein the plurality of first terminal sections are aligned at ends of the sealing resin on a first side and a second side in the second direction as viewed in the thickness direction,
the plurality of second terminal sections are aligned at ends of the sealing resin on a first side and a second side in the first direction as viewed in the thickness direction,
each of the plurality of first terminal sections includes two first inner surfaces connected to one of the first mounting surfaces and one of the first side surfaces, the two first inner surfaces facing the first side and the second side in the first direction, respectively,
each of the plurality of second terminal sections includes two second inner surfaces connected to one of the second mounting surfaces and one of the second side surfaces, the two second inner surfaces facing the first side and the second side in the second direction, respectively, and
the first inner surfaces and the second inner surfaces are covered with the sealing resin.

### Clause 10

The semiconductor device according to clause 9, wherein the lead includes a third terminal section arranged at a position closer to an end of the sealing resin than the plurality of first terminal sections in the first direction and closer to an end of the sealing resin than the plurality of second terminal sections in the second direction,
the third terminal section includes a third mounting surface facing the second side in the thickness direction, a third side surface facing a same side as the first side surface, and a fourth side surface facing a same side as the second side surface,
the third mounting surface, the third side surface, and the fourth side surface are exposed from the sealing resin, and
the third mounting surface, the third side surface, and the fourth side surface are entirely formed of the metal layer.

### Clause 11

The semiconductor device according to clause 10, wherein the sealing resin has a rectangular shape extending in the first direction and the second direction as viewed in the thickness direction, and
the third terminal section comprises a plurality of third terminal sections each arranged at one of four corners of the sealing resin as viewed in the thickness direction.

### Clause 12

The semiconductor device according to any of clauses 1 to 11, wherein the main section is connected to at least one of the plurality of first terminal sections, and
the semiconductor element includes a plurality of electrodes arranged on a side opposite from the obverse surface in the thickness direction and connected to the obverse surface.

### Clause 13

The semiconductor device according to any of clauses 1 to 12, wherein the metal layer comprises a plating layer.

### Clause 14

A method for manufacturing a semiconductor device, comprising the steps of: forming a sealing resin covering a portion of each of a plurality of terminal sections made of a base member, and a semiconductor element;
forming a groove in each of the plurality of terminal sections such that the groove is recessed in a thickness direction from a mounting surface of each of the plurality of terminal sections facing in the thickness direction;
forming a metal layer by plating such that the metal layer covers the mounting surface and the groove; and
cutting the sealing resin along the groove,
wherein in the step of forming the groove, each of the plurality of terminal sections is cut through an entire thickness thereof.

### REFERENCE NUMERALS

A10, A11: Semiconductor device 1: Lead
1A: Base member 1B: Metal layer
10: Main section 101: First main section
102: Second main section 103: Third main section
104: Fourth main section 105: Fifth main section
11: Obverse surface 111: First obverse surface
112: Second obverse surface 113: Third obverse surface
114: Fourth obverse surface 115: Fifth obverse surface
12: Reverse surface 121: First reverse surface
122: Second reverse surface 20: Terminal section
201: Mounting surface 202: Groove
205: Cut side surface 21: First terminal section
211: First mounting surface 212: First side surface
213: First inner surface 22: Second terminal section
221: Second mounting surface 222: Second side surface
223: Second inner surface 23: Third terminal section
231: Third mounting surface 232: Third side surface
233: Fourth side surface 3: Semiconductor element
31: Semiconductor substrate 32: Semiconductor layer
321: Switching circuit 322: Control circuit
34, 35: Electrode 4: Sealing resin
41: Resin obverse surface 42: Resin reverse surface
431, 432: First resin side surface
433, 434: Second resin side surface
441, 442: First resin intermediate surface
443, 444: Second resin intermediate surface
451, 452: First resin inner side surface
453, 454: Second resin inner side surface
81, 82: Blade 90: Tape
L1, L2: Line x: First direction
y: Second direction z: Thickness direction

1. A semiconductor device comprising:
a lead including a main section that includes an obverse surface facing a first side in a thickness direction;
a semiconductor element supported by the obverse surface; and
a sealing resin covering a portion of the lead and the semiconductor element,
wherein the lead includes a base member and a metal layer covering a portion of the base member,
the lead includes a plurality of first terminal sections aligned in a first direction perpendicular to the thickness direction,
each of the plurality of first terminal sections includes a first mounting surface facing a second side in the thickness direction, and a first side surface facing in a second direction perpendicular to the thickness direction and the first direction,
the first mounting surface and the first side surface are exposed from the sealing resin, and
the first mounting surface and the first side surface are entirely formed of the metal layer.

2. The semiconductor device according to claim 1, wherein the sealing resin includes a first resin side surface located at an end in the second direction and facing in the second direction, and
the first side surface is located inward of the sealing resin from the first resin side surface as viewed in the thickness direction.

3. The semiconductor device according to claim 2, wherein the sealing resin includes a first resin intermediate surface connected to an end of the first resin side surface on the second side in the thickness direction, and
the first resin intermediate surface faces the second side in the thickness direction and is located between the first side surface and the first resin side surface in the second direction.

4. The semiconductor device according to claim 1, wherein the first side surface is connected to the first mounting surface and flush with another one of the first side surfaces.

5. The semiconductor device according to claim 1, wherein the lead includes a plurality of second terminal sections aligned in the second direction,
each of the plurality of second terminal sections includes a second mounting surface facing the second side in the thickness direction, and a second side surface facing in the first direction,
the second mounting surface and the second side surface are exposed from the sealing resin, and
the second mounting surface and the second side surface are entirely formed of the metal layer.

6. The semiconductor device according to claim 5, wherein the sealing resin includes a second resin side surface located at an end in the first direction and facing in the first direction, and
the second side surface is located inward of the sealing resin from the second resin side surface as viewed in the thickness direction.

7. The semiconductor device according to claim 6, wherein the sealing resin includes a second resin intermediate surface connected to an end of the second resin side surface on the second side in the thickness direction, and
the second resin intermediate surface faces the second side in the thickness direction and is located between the second side surface and the second resin side surface in the first direction.

8. The semiconductor device according to claim 5, wherein the second side surface is connected to the second mounting surface and flush with another one of the second side surfaces.

9. The semiconductor device according to claim 5, wherein the plurality of first terminal sections are aligned at ends of the sealing resin on a first side and a second side in the second direction as viewed in the thickness direction,
the plurality of second terminal sections are aligned at ends of the sealing resin on a first side and a second side in the first direction as viewed in the thickness direction,
each of the plurality of first terminal sections includes two first inner surfaces connected to one of the first mounting surfaces and one of the first side surfaces, the two first inner surfaces facing the first side and the second side in the first direction, respectively,
each of the plurality of second terminal sections includes two second inner surfaces connected to one of the second mounting surfaces and one of the second side surfaces, the two second inner surfaces facing the first side and the second side in the second direction, respectively, and
the first inner surfaces and the second inner surfaces are covered with the sealing resin.

10. The semiconductor device according to claim 9, wherein the lead includes a third terminal section arranged at a position closer to an end of the sealing resin than the plurality of first terminal sections in the first direction and closer to an end of the sealing resin than the plurality of second terminal sections in the second direction,
the third terminal section includes a third mounting surface facing the second side in the thickness direction, a third side surface facing a same side as the first side surface, and a fourth side surface facing a same side as the second side surface,
the third mounting surface, the third side surface, and the fourth side surface are exposed from the sealing resin, and
the third mounting surface, the third side surface, and the fourth side surface are entirely formed of the metal layer.

11. The semiconductor device according to claim 10, wherein the sealing resin has a rectangular shape extending in the first direction and the second direction as viewed in the thickness direction, and
the third terminal section comprises a plurality of third terminal sections each arranged at one of four corners of the sealing resin as viewed in the thickness direction.

12. The semiconductor device according to claim 1,
wherein the main section is connected to at least one of the plurality of first terminal sections, and
the semiconductor element includes a plurality of electrodes arranged on a side opposite from the obverse surface in the thickness direction and connected to the obverse surface.

13. The semiconductor device according to claim 1, wherein the metal layer comprises a plating layer.

14. A method for manufacturing a semiconductor device, comprising the steps of:
forming a sealing resin covering a portion of each of a plurality of terminal sections made of a base member, and a semiconductor element;
forming a groove in each of the plurality of terminal sections such that the groove is recessed in a thickness direction from a mounting surface of each of the plurality of terminal sections facing in the thickness direction;
forming a metal layer by plating such that the metal layer covers the mounting surface and the groove; and
cutting the sealing resin along the groove,
wherein in the step of forming the groove, each of the plurality of terminal sections is cut through an entire thickness thereof.
